(19) United States
(12) Patent Application Publication
(10) Pub. No.: US 2010/0300744 A1
(43) Pub. Date: Dec. 2, 2010

(54) ELECTROMAGNETIC SHIELDING ARTICLE

(75) Inventors: Walter R. Romanko, Austin, TX (US); Jeffrey A. Lim, Austin, TX (US); Sywong Ngin, Austin, TX (US); Eugene P. Janulis, JR., Austin, TX (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/782,746

(22) Filed: May 19, 2010

Related U.S. Application Data
(60) Provisional application No. 61/181,750, filed on May 28, 2009.

(51) Int. Cl. H05K 9/00

(52) U.S. Cl. 174/388; 174/350

(57) ABSTRACT

A shielding article includes a first conductive layer and a second conductive layer spaced apart from the first conductive layer by a non-conductive polymeric layer defining a separation distance. The first conductive layer and the second conductive layer cooperatively provide a first shielding effectiveness. The first conductive layer, the second conductive layer, and the separation distance cooperatively provide a second shielding effectiveness that is greater than the first shielding effectiveness.

### CROSS REFERENCE TO RELATED APPLICATION

This application claims the benefit of U.S. Provisional Patent Application No. 61/181,750, filed May 28, 2009, the disclosure of which is incorporated by reference herein in its entirety.

### TECHNICAL FIELD

The present invention relates to electromagnetic shielding articles suitable for use in electromagnetic interference (EMI) shielding applications. In particular, the present invention relates to multilayer electromagnetic shielding articles that significantly increase shielding effectiveness.

### BACKGROUND

In recent years, electronic communications devices, such as, e.g., mobile phones, televisions, gaming electronics, cameras, RFID security devices, medical devices, and electronic devices in automotive and aerospace applications, have become increasingly smaller, and operating frequencies for electronic communications have become higher. As a result, it is desirable to provide effective electromagnetic wave shielding for electronic devices, so that an electronic device does not emit in excess of a permissible amount of electromagnetic interference (EMI), and does not receive external emissions of electromagnetic waves from another device. It has become more challenging to satisfy these requirements with conventional electromagnetic shielding articles because of their limitations in shielding effectiveness, flexibility, and durability.

### SUMMARY

In one aspect, the present invention provides a shielding article including a first conductive layer and a second conductive layer spaced apart from the first conductive layer by a non-conductive polymeric layer defining a separation distance. The first conductive layer and the second conductive layer cooperatively provide a first shielding effectiveness. The first conductive layer, the second conductive layer, and the separation distance cooperatively provide a second shielding effectiveness that is greater than the first shielding effectiveness.

In another aspect, the present invention provides a shielding article including a plurality of conductive layers, each conductive layer spaced apart from an adjacent conductive layer by a non-conductive polymeric layer defining a separation distance. The conductive layers cooperatively provide a first shielding effectiveness. The conductive layers and separation distances cooperatively provide a second shielding effectiveness that is greater than the first shielding effectiveness.

The above summary of the present invention is not intended to describe each disclosed embodiment or every implementation of the present invention. The Figures and detailed description that follow below more particularly exemplify illustrative embodiments.

### BRIEF DESCRIPTION OF THE DRAWINGS

FIG. 1 is a schematic cross-sectional view of an exemplary embodiment of a shielding article according to an aspect of the present invention.

FIG. 2 is a schematic cross-sectional view of another exemplary embodiment of a shielding article according to an aspect of the present invention.

FIG. 3 is a schematic cross-sectional view of another exemplary embodiment of a shielding article according to an aspect of the present invention.

FIG. 4 is a schematic cross-sectional view of another exemplary embodiment of a shielding article according to an aspect of the present invention.

FIG. 5 is a graph illustrating the improved shielding effectiveness achieved by shielding articles according to aspects of the present invention.

FIG. 6 is another graph illustrating the improved shielding effectiveness achieved by shielding articles according to aspects of the present invention.

### DETAILED DESCRIPTION

In the following detailed description of the preferred embodiments, reference is made to the accompanying drawings that form a part hereof. The accompanying drawings show, by way of illustration, specific embodiments in which the invention may be practiced. It is to be understood that other embodiments may be utilized, and structural or logical changes may be made without departing from the scope of the present invention. The following detailed description, therefore, is not to be taken in a limiting sense, and the scope of the invention is defined by the appended claims.

In one aspect, the present invention includes a multi-layer shielding article that is useful for shielding of electronic communications devices by interfering with or cutting off the electrical or magnetic signal emitted from electromagnetic equipment, electronics equipment, receiving devices, or other external devices.

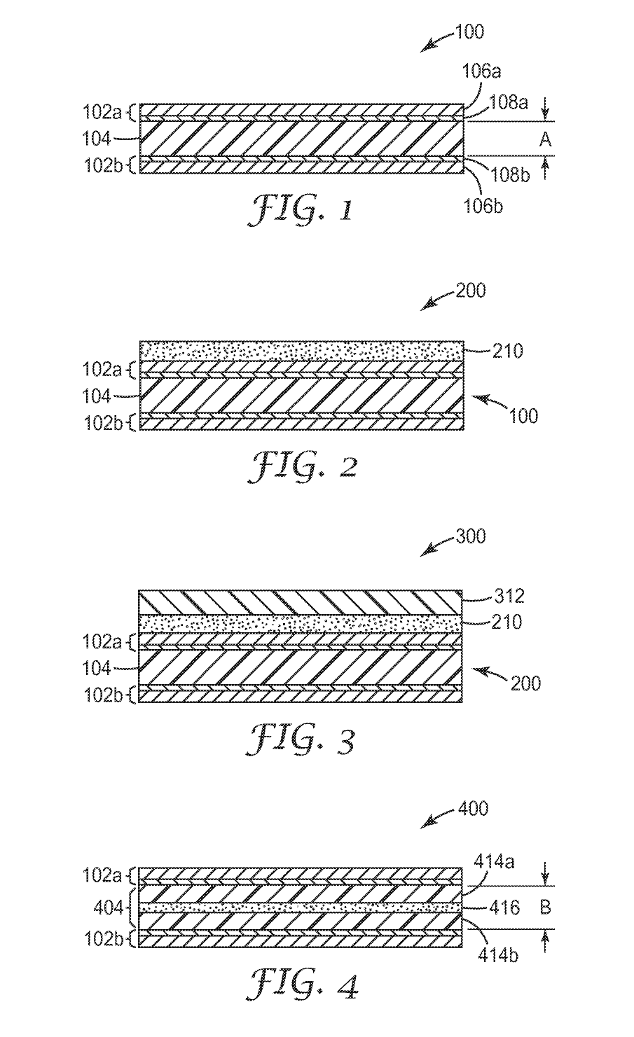

FIG. 1 illustrates an exemplary embodiment of a shielding article according to an aspect of the present invention. Shielding article 100 includes a first conductive layer 102a and a second conductive layer 102b (collectively referred to herein as “conductive layers 102”). Second conductive layer 102b is spaced apart from first conductive layer 102a by a non-conductive polymeric layer 104. “Non-conductive” is defined herein as substantially not electrically conductive. Polymeric layer 104 defines a separation distance A, which in this embodiment substantially corresponds with the thickness of polymeric layer 104. First conductive layer 102a and second conductive layer 102b cooperatively provide a first shielding effectiveness. The first shielding effectiveness is based on a double-thickness single conductive layer which is effectively equal to two adjacent single-thickness conductive layers 102a and 102b. Unexpectedly, first conductive layer 102a, second conductive layer 102b, and separation distance A cooperatively provide a second shielding effectiveness that is greater than the first shielding effectiveness.

Conductive layers 102 may be formed by metalizing polymeric layer 104, such as, e.g., by chemical deposition (such as, e.g., electroplating), physical deposition (such as, e.g., sputtering), or any other suitable method. Alternatively, conductive layers 102 may be laminated onto polymeric layer 104. In one embodiment, conductive layers 102 each have a thickness in the range of 100 to 30000 Angstroms (10 to 3000 nm). In the embodiment of FIG. 1, conductive layers 102a and 102b have substantially the same thickness. In other embodiments, conductive layers 102a and 102b may have a different thickness. Conductive layers 102 may include any suitable conductive material, including but not limited to copper, silver, aluminum, gold, and alloys thereof. First conductive layer 102a may include a different material or combination of materials than second conductive layer 102b. For example, first conductive layer 102a may include a layer of copper and second conductive layer 102b may include a layer of silver.

Polymeric layer 104 may include any suitable polymeric material, including but not limited to polyester, polyimide, polyamide-imide, polytetrafluoroethylene, polypropylene, polyethylene, polyphenylene sulfide, polyethylene naphthalate, polycarbonate, silicone rubber, ethylene propylene diene rubber, polyurethane, acrylate, silicone, natural rubber, epoxies, and synthetic rubber adhesive. Polymeric layer 104 may include one or more additives and/or fillers to provide properties suitable for the intended application. Adhesive materials, additives, and fillers that may be included in polymeric layer 104 are described in more detail below. Polymeric layer 104 may include non-wovens, fabrics, foams, or a substantially hollow polymeric or adhesive layer. In one embodiment, polymeric layer 104 has a thickness in the range of 5 μm to 500 μm.

In the embodiment shown in FIG. 1, first and second conductive layers 102a and 102b each include a layer of copper 106a and 106b (collectively referred to herein as “copper layers 106”), respectively, disposed on a layer of nickel 108a and 108b (collectively referred to herein as “nickel layers 108”), respectively (also referred to as “priming”). Nickel layers 108 and copper layers 106 are deposited using any suitable method known in the art. Polymeric layer 104 provides sufficient flexibility for the final use of shielding article 100, while it also has sufficient rigidity, thermal stability, and chemical stability, e.g., for use in the metal deposition process. Nickel layers 108 provide better adhesion of copper layers 106 to polymeric layer 104 than copper layers 106 alone. Copper layers 106 provide sufficient electrical conductivity to allow the construction to act as a shielding article for use in mobile phones, televisions, gaming electronics, cameras, RFID security devices, medical devices, and electronic devices in automotive and aerospace applications, for example. In other embodiments, an additional layer of nickel may be deposited onto the outer surface of copper layers 106 to provide corrosion protection to copper layers 106. In one embodiment, nickel layers 108 each have a thickness in the range of 25 to 125 Angstroms (2.5 to 12.5 nm) and copper layers 106 each have a thickness in the range of 50 to 2000 Angstroms (5 to 200 nm). In a preferred embodiment, nickel layers 108 each have a thickness in the range of 50 to 100 Angstroms (5 to 10 nm) and copper layers 106 each have a thickness in the range of 800 to 2000 Angstroms (80 to 200 nm). The preferred ranges of material thickness allow a desired balance of material flexibility and reliability, while providing adequate amounts of material for electrical conductivity and corrosion protection. Although in the illustrated embodiment, copper layers 106a and 106b have substantially the same thickness, in other embodiments, copper layers 106a and 106b may have a different thickness. Similarly, although in the illustrated embodiment, nickel layers 108a and 108b have substantially the same thickness, in other embodiments, nickel layers 108a and 108b may have a different thickness. Although in the illustrated embodiment, copper layers 106 are deposited onto nickel layers 108, in other embodiments, one or both of copper layers 106 may be deposited directly onto polymeric layer 104. Nickel layers 108 are defined herein as layers including at least one of nickel (Ni), nickel alloys, and austenitic nickel-based superalloys, such as, e.g., the austenitic nickel-based superalloy available under the trade designation INCONEL from Special Metals Corporation, New Hartford, N.Y., U.S.A. Copper layers 106 are defined herein as layers including at least one of copper (Cu) and copper alloys.

FIG. 2 illustrates another exemplary embodiment of a shielding article according to an aspect of the present invention. Shielding article 200 includes shielding article 100 as described above and an adhesive layer 210 disposed on first conductive layer 102a. In other embodiments, an adhesive layer 210 may be disposed on second conductive layer 102b or on both first and second conductive layers 102a, 102b. In one embodiment, adhesive layer 210 is used to bond shielding article 200 to a protective layer, or a device or component that needs to be electromagnetically shielded, for example. Adhesive layer 210 may include a pressure sensitive adhesive (PSA), a hot melt adhesive, a thermoset adhesive, a curable adhesive, or any other suitable adhesive. Adhesive layer 210 may include one or more additives and/or fillers to provide properties suitable for the intended application. Adhesive materials, additives, and fillers that may be included in adhesive layer 210 are described in more detail below. Adhesive layer 210 may include a corrosion inhibitor. In one embodiment, adhesive layer 210 has a thickness in the range of 10 μm to 150 μm.

FIG. 3 illustrates another exemplary embodiment of a shielding article according to an aspect of the present invention. Shielding article 300 includes shielding article 200 as described above and a protective layer 312 disposed adjacent adhesive layer 210. In this embodiment, protective layer 312 is bonded to first conductive layer 102a by adhesive layer 210. In other embodiments, a protective layer 312 may be disposed adjacent second conductive layer 102b or adjacent both first and second conductive layers 102a, 102b. In one embodiment, protective layer 312 includes a polyester paper coated with an inorganic coating, such as, e.g., the polyester paper coated with an inorganic coating available under the trade designation TufQUIN from 3M Company, St. Paul, Minn., U.S.A. TufQUIN offers the high-temperature capabilities of inorganic materials combined with the high mechanical strength gained by the use of organic fiber. TufQUIN papers can be combined with polyester film to form a flexible laminate uniquely suited for high temperature electrical insulation applications. In another embodiment, protective layer 312 includes an aramid paper, such as, e.g., the aramid paper available under the trade designation NOMEX from E. I. du Pont de Nemours and Company, Wilmington, Del., U.S.A. Protective layer 312 is typically capable of offering chemical protection (such as, e.g., protection against corrosion) as well as physical protection (such as, e.g., protection against abrasion). Protective layer 312 may have any thickness suitable for the intended application.

FIG. 4 illustrates another exemplary embodiment of a shielding article according to an aspect of the present invention. Shielding article 400 includes a first conductive layer 102a and a second conductive layer 102b as described above. Second conductive layer 102b is spaced apart from first conductive layer 102a by a non-conductive polymeric layer 404. Polymeric layer 404 defines a separation distance B, which in this embodiment substantially corresponds with the thickness of polymeric layer 404. First conductive layer 102a and second conductive layer 102b cooperatively provide a first shielding effectiveness. Unexpectedly, first conductive layer 102a, second conductive layer 102b, and separation distance B cooperatively provide a second shielding effectiveness that is greater than the first shielding effectiveness. Polymeric layer 404 includes a first non-conductive polymeric sublayer 414a, a second non-conductive polymeric sublayer 414b, and a bonding adhesive layer 416 disposed between first polymeric sublayer 414a and second polymeric sublayer 414b. In one embodiment, first and second polymeric sublayers 414a and 414b are identical to polymeric layer 104 as described above. A useful advantage of this construction of polymeric layer 404 is in the method of making shielding article 400. In one embodiment, shielding article 400 is made as follows: First, conductive layer 102a is deposited onto first polymeric sublayer 414a, and second conductive layer 102b is deposited onto second polymeric sublayer 414b, resulting in two separate constructions. Then, bonding adhesive layer 416 is laminated to first polymeric sublayer 414a, and second polymeric sublayer 414b is laminated to bonding adhesive layer 416, combining the two separate constructions into shielding article 400. Bonding adhesive layer 416 may include a pressure sensitive adhesive (PSA), a hot melt adhesive, a thermoset adhesive, a curable adhesive, or any other suitable adhesive. Bonding adhesive layer 416 may include one or more additives and/or fillers to provide properties suitable for the intended application. Adhesive materials, additives, and fillers that may be included in bonding adhesive layer 416 are described in more detail below. Adhesive layers of a shielding article according to an aspect of the present invention, such as, e.g., adhesive layers 210 and 416, may include any of the various types of materials used for bonding, adhering, or otherwise affixing one material or surface to another. Classes of adhesives include, for instance, pressure sensitive adhesives, hot melt adhesives, thermoset adhesives, and curable adhesives. The pressure sensitive adhesives include those based on silicone polymers, acrylate polymers, natural rubber polymers, and synthetic rubber polymers. They may be tackified, crosslinked, and/or filled with various materials to provide desired properties. Hot melt adhesives become tacky and adhere well to substrates when they are heated above a specified temperature and/or pressure; when the adhesive cools down, its cohesive strength increases while retaining a good bond to the substrate. Examples of types of hot melt adhesives include, but are not limited to, polyamides, polyurethanes, copolymers of ethylene and vinyl acetate, and olefinic polymers modified with more polar species such as maleic anhydride. Thermoset adhesives are adhesives that can create an intimate contact with a substrate either at room temperature or with the application of heat and/or pressure. With heating, a chemical reaction occurs in the thermoset to provide long term cohesive strength at ambient, subambient, and elevated temperatures. Examples of thermoset adhesives include epoxies, silicones, and polyesters, and polyurethanes. Curable adhesives can include thermosets, but are differentiated here in that they can cure at room temperature, either with or without the addition of external chemical species or energy. Examples include two-part epoxies and polyesters, one-part moisture cure silicones and polyurethanes, and adhesives utilizing actinic radiation to cure such as UV, visible light, or electron beam energy.

Non-conductive polymeric layers and adhesive layers of a shielding article according to an aspect of the present invention, such as, e.g., polymeric layer 104, polymeric sublayers 414a and 414b, and adhesive layers 210 and 416, may include various types of additives and fillers alone or in combination to provide properties suitable for the intended application. Typical additives and fillers include plasticizers, thermal stabilizers, antioxidants, UV stabilizers, pigments, dyes, flame retardants, smoke suppressants, conductive fillers, species to improve chemical resistance, and other property modifiers.

Flame retardants represent another class of filler useful for some applications to ensure that the overall product construction minimizes, ameliorates, or eliminates the propagation of fire. Types of flame retardants can include halogenated flame retardants such as decabromo dipehnyl oxide, chlorinated paraffin wax, brominated phenols, and brominated bisphenol A. Furthermore, formulations which employ halogenated flame retardants often include antimony oxides such as antimony trioxide which act synergistically to enhance the flame retarding abilities of the halogen compound.

Another type of flame retardant relies on intumescence or char formation to reduce the polymer flammability and block combustion. Some examples of intumescent flame retardants include phosphates such as ammonium polyphosphate and nitrogen compounds such as melamine. Another class of flame retardant block flame propagation by generating inert gasses and promoting char formation upon decomposition. These include inorganic hydroxides, hydroxycarbonates and carbonates such as aluminum trihydrate, magnesium hydroxide and magnesium carbonate.

Other classes of flame retardants include molybdenates and borates which also suppress smoke generation. Some examples of these types of flame retardants include ammonium octomolybdenate and zinc borate. Any combination of these and other well known flame retardants may be included.

Other types of fillers that may be included, e.g., to enhance overall performance or reduce cost, include titanium dioxide, fumed silica, carbon fibers, carbon black, glass beads, glass fibers, glass bubbles, mineral fibers, clay particles, organic fibers, zinc oxide, aluminum oxide, boron nitride, aluminum nitride, barium titanate, molybdenum and the like.

One important filler useful for some shielding applications is a conductive particle to provide the flow of electrical current from the shielding layer to a ground plane. The conductive particles can be any of the types of particles currently used, such as spheres, flakes, rods, cubes, amorphous, or other particle shapes. They may be solid or substantially solid particles such as carbon black, carbon fibers, nickel spheres, nickel coated copper spheres, metal-coated oxides, metal-coated polymer fibers, or other similar conductive particles. These conductive particles can be made from electrically insulating materials that are plated or coated with a conductive material such as silver, aluminum, nickel, or indium tin-oxide. The metal-coated insulating material can be substantially hollow particles such as hollow glass spheres, or may comprise solid materials such as glass beads or metal oxides. The conductive particles may be on the order of several tens of microns to nanometer sized materials such as carbon nanotubes. The conductive adhesive can also be comprised of a conductive polymeric matrix.

Shielding articles according to aspects of the present invention have numerous advantages for their intended use as compared to conventional shielding articles. One particular advantage is an unexpected performance in electromagnetic shielding, which is described in greater detail below.

### EXAMPLES

Shielding effectiveness measurements on shielding articles according to aspects of the present invention and on conventional shielding articles were conducted. The shielding effectiveness measurements were conducted generally following the Standard Test Method for Measuring the Electromagnetic Shielding Effectiveness of Planar Materials ASTM D 4935-99. Measurements were performed on an Agilent Technologies N5230A PNA-L Network Analyzer outfitted with a TEM cell, and the IF Bandwidth and number of scans averaged were adjusted as necessary to accurately measure the shielding level of the various samples. The following test samples were prepared.

Comparative test sample C501 was a sample of a conventional shielding article including a single conductive layer deposited onto a non-conductive polymeric layer. Specifically, comparative test sample C501 was created as follows: A layer of nickel having a thickness of about 75 Angstroms (7.5 nm) was deposited onto a polymeric layer including polyethylene terephthalate and having a thickness of about 2.0 mil (51 μm). A layer of copper having a thickness of about 1100 Angstroms (110 nm) was deposited onto the layer of nickel.

Test sample 502 was a sample of a shielding article according to an aspect of the present invention. Specifically, test sample 502 was created as follows: A layer of nickel having a thickness of about 75 Angstroms (7.5 nm) was deposited onto a polymeric layer including polyethylene terephthalate and having a thickness of about 2.0 mil (51 μm). A first layer of copper having a thickness of about 550 Angstroms (55 nm) was deposited onto the layer of nickel. A second layer of copper having a thickness of about 550 Angstroms (55 nm) was deposited onto the opposing surface of the polymeric layer.

Test sample 503 was a sample of another shielding article according to an aspect of the present invention. Specifically, test sample 503 was created as follows: A first layer of nickel having a thickness of about 75 Angstroms (7.5 nm) was deposited onto a first polymeric layer including polyethylene terephthalate and having a thickness of about 2.0 mil (51 μm). A first layer of copper having a thickness of about 550 Angstroms (55 nm) was deposited onto the first layer of nickel. A second layer of nickel having a thickness of about 75 Angstroms (7.5 nm) was deposited onto a second polymeric layer separate from the first polymeric layer. A second layer of copper having a thickness of about 550 Angstroms (55 nm) was deposited onto the second layer of nickel. A bonding adhesive layer including an acrylate pressure sensitive adhesive and having a thickness of about 1.0 mil (25 μm) was laminated to the first polymeric layer. The second polymeric layer was laminated to the bonding adhesive layer.

Test sample 504 was a sample of another shielding article according to an aspect of the present invention. Specifically, test sample 504 was created as follows: A first layer of nickel having a thickness of about 75 Angstroms (7.5 nm) was deposited onto a first polymeric layer including polyethylene terephthalate and having a thickness of about 2.0 mil (51 μm). A first layer of copper having a thickness of about 550 Angstroms (55 nm) was deposited onto the first layer of nickel. A second layer of nickel having a thickness of about 75 Angstroms (7.5 nm) was deposited onto a second polymeric layer separate from the first polymeric layer. A second layer of copper having a thickness of about 550 Angstroms (55 nm) was deposited onto the second layer of nickel. A bonding adhesive layer including an acrylate pressure sensitive adhesive and having a thickness of about 5.0 mil (127 μm) was laminated to the first polymeric layer. The second polymeric layer was laminated to the bonding adhesive layer.

TABLE 1

| | | | | | Additional |
|---|---|---|---|---|---|
| | | | Separation | | Shielding |
| | Number of | | Between | Average | Compared to |
| | Specimen | | Copper Layers | Shielding | Sample C501 |
| | Averaged | Copper Layering | (μm) | (dB) | (dB) |
| Sample C501 | 6 | Single Layer | 0 | −55.7 | N/A |
| | | 1100 Angstroms | | | |
| Sample 502 | 6 | Dual Layer | 51 | −66.9 | −11.2 |
| | | 550 Angstroms Each | | | |
| Sample 503 | 4 | Dual Layer | 127 | −71.4 | −15.7 |
| | | 550 Angstroms Each | | | |
| Sample 504 | 3 | Dual Layer | 229 | −78.4 | −22.7 |
| | | 550 Angstroms Each | | | |

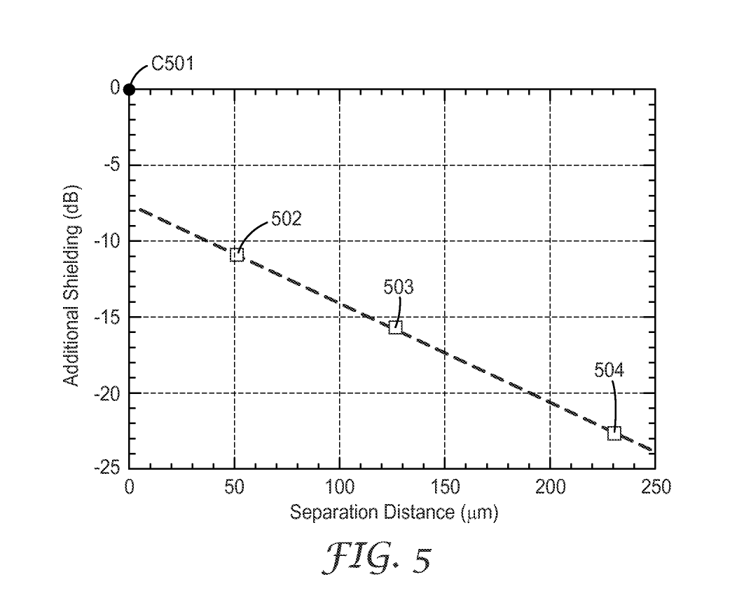

Table 1 and FIG. 5 present the shielding data, averaged from 100 to 1000 MHz for samples C501-504. The shielding effectiveness of comparative test sample C501 was measured at −55.7 dB over the range of 100 through 1000 MHz. By effectively dividing in half and spacing apart the single layer of copper of comparative test sample C501 by a separation distance of about 51 μm, resulting in a construction substantially identical to that of test sample 502, the shielding effectiveness was unexpectedly increased to −66.9 dB (−11.2 dB additional shielding). This data illustrates that the presence of a separation distance between conductive layers of a shielding article unexpectedly increases the shielding effectiveness of the shielding article. By increasing the separation distance to about 127 μm (test sample 503) and 229 μm (test sample 504), the shielding effectiveness was further increased to −71.4 dB (−15.7 dB additional shielding) and −78.4 dB (−22.7 dB additional shielding), respectively. This data illustrates that as the separation distance is increased, the shielding effectiveness increases. FIG. 5 further illustrates that in the limit as the layer separation decreases towards zero, the extrapolated value (y-intercept) is not zero. This demonstrates the unexpected synergy of utilizing dual layer shielding layers versus a single layer having substantially the same effective thickness.

Additional shielding effectiveness measurements on shielding articles according to aspects of the present invention and on conventional shielding articles were conducted. The shielding effectiveness measurements were conducted as described above. The following test samples were prepared.

Comparative test sample C601 was a sample of a conventional shielding article including a single conductive layer including an aluminum foil having a thickness of about 0.9 mil (23 μm).

Test sample 602 was a sample of a shielding article according to an aspect of the present invention. Specifically, test sample 602 was created as follows: A first conductive layer including an aluminum foil having a thickness of about 0.4 mil (10 μm) was laminated to a polymeric layer including acrylate bonding adhesive having a thickness of about 1.0 mil (25 μm). A second conductive layer including an aluminum foil having a thickness of about 0.4 mil (10 μm) was laminated to the opposing surface of the polymeric layer.

Test sample 603 was a sample of a shielding article according to an aspect of the present invention. Specifically, test sample 603 was created as follows: A first conductive layer including an aluminum foil having a thickness of about 0.4 mil (10 μm) was laminated to a polymeric layer including acrylate bonding adhesive having a thickness of about 2.0 mil (51 μm). A second conductive layer including an aluminum foil having a thickness of about 0.4 mil (10 μm) was laminated to the opposing surface of the polymeric layer.

Test sample 604 was a sample of a shielding article according to an aspect of the present invention. Specifically, test sample 604 was created as follows: A first conductive layer including an aluminum foil having a thickness of about 0.4 mil (10 μm) was laminated to a polymeric layer including acrylate bonding adhesive having a thickness of about 4.0 mil (102 μm). A second conductive layer including an aluminum foil having a thickness of about 0.4 mil (10 μm) was laminated to the opposing surface of the polymeric layer.

Test sample 605 was a sample of a shielding article according to an aspect of the present invention. Specifically, test sample 605 was created as follows: A first conductive layer including an aluminum foil having a thickness of about 0.4 mil (10 μm) was laminated to a polymeric layer including acrylate bonding adhesive having a thickness of about 6.0 mil (152 μm). A second conductive layer including an aluminum foil having a thickness of about 0.4 mil (10 μm) was laminated to the opposing surface of the polymeric layer.

TABLE 2

| | | | | | Additional |
|---|---|---|---|---|---|
| | | | Separation | | Shielding |
| | Number of | | Between | Average | Compared to |
| | Specimen | | Aluminum Layers | Shielding | Sample C601 |
| | Averaged | Aluminum Layering | (μm) | (dB) | (dB) |
| Sample C601 | 2 | Single Layer | 0 | −112.1 | N/A |
| | | 23 μm | | | |
| Sample 602 | 2 | Dual Layer | 25 | −123.4 | −11.3 |
| | | 10 μm Each | | | |
| Sample 603 | 2 | Dual Layer | 51 | −123.6 | −11.4 |
| | | 10 μm Each | | | |
| Sample 604 | 2 | Dual Layer | 102 | −126.4 | −14.2 |
| | | 10 μm Each | | | |
| Sample 605 | 2 | Dual Layer | 152 | −128.4 | −16.2 |
| | | 10 μm Each | | | |

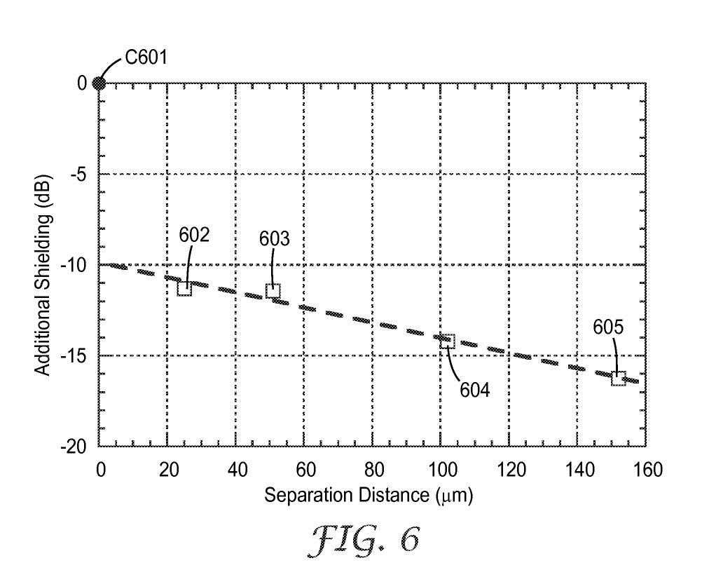

Table 2 and FIG. 6 present the shielding data, averaged from 100 to 1000 MHz of samples C601-605. The shielding effectiveness of comparative test sample C601 was measured at −112.1 dB over the range of 100 through 1000 MHz. By effectively dividing in half and spacing apart the single layer of aluminum of comparative test sample C601 by a separation distance of about 25 μm, resulting in a construction substantially identical to that of test sample 602, the shielding effectiveness was unexpectedly increased to −123.4 dB (−11.3 dB additional shielding). This data illustrates that the presence of a separation distance between conductive layers of a shielding article unexpectedly increases the shielding effectiveness of the shielding article. By increasing the separation distance to about 51 μm (test sample 603), 102 μm (test sample 604), and 152 μm (test sample 605), the shielding effectiveness was further increased to −123.6 dB (−11.4 dB additional shielding), −126.4 dB (−14.2 dB additional shielding), and −128.4 dB (−16.2 dB additional shielding), respectively. This data illustrates that as the separation distance is increased, the shielding effectiveness increases. FIG. 6 further illustrates that in the limit as the layer separation decreases towards zero, the extrapolated value (y-intercept) is not zero. This demonstrates the unexpected synergy of utilizing dual layer shielding layers versus a single layer having substantially the same effective thickness.

In combination, the data presented in Tables 1-2 and FIGS. 5-6 illustrates that additional shielding effectiveness can be achieved in shielding articles according to aspects of the present invention including first and second conductive layers including different conductive materials.

Additional shielding effectiveness measurements on shielding articles according to an aspect of the present invention were conducted. The shielding effectiveness measurements were conducted as described above. The following test sample was prepared.

Test sample 701 was a sample of a shielding article according to an aspect of the present invention. Specifically, test sample 701 was created as follows: A layer of nickel having a thickness of about 150 Angstroms (15 nm) was deposited onto a polymeric layer including polyethylene terephthalate and having a thickness of about 2.0 mil (51 μm). A layer of copper having a thickness of about 1800 Angstroms (180 nm) was deposited onto the layer of nickel. A layer of titanium having a thickness of about 150 Angstroms (15 nm) was deposited onto the opposing surface of the polymeric layer. A layer of silver having a thickness of about 1000 Angstroms (100 nm) was deposited onto the layer of titanium. The average shielding effectiveness of test sample 701 was measured at −81.6 dB, whereby 4 specimens were averaged. This example demonstrates that a shielding article wherein a first conductive layer and a second conductive layer include different conductive materials can be utilized effectively. It also demonstrates that the thickness of the first and second conductive layers may be different.

It has been demonstrated that a shielding article including a first conductive layer spaced apart from a second conductive layer (i.e., dual layer construction) has a greater shielding effectiveness than a shielding article wherein the first conductive layer and the second conductive layer essentially form a single conductive layer (i.e., single layer construction). Based on this, a person of ordinary skill in the art will easily understand that a shielding article including a plurality conductive layers, each conductive layer spaced apart from an adjacent conductive layer (i.e., multi-layer construction) will have a greater shielding effectiveness than a shielding article wherein the conductive layers form a single conductive layer (i.e., single layer construction). For example, in a shielding article including a first conductive layer spaced apart from a second conductive layer, by dividing in half and separating one or both of first and second conductive layers (resulting in a three- or four-layer construction), the shielding effectiveness of the shielding article will further increase.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the mechanical, electro-mechanical, and electrical arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. A shielding article comprising:
a first conductive layer; and
a second conductive layer spaced apart from the first conductive layer by a non-conductive polymeric layer defining a separation distance,
wherein the first conductive layer and the second conductive layer cooperatively provide a first shielding effectiveness, and wherein the first conductive layer, the second conductive layer, and the separation distance cooperatively provide a second shielding effectiveness that is greater than the first shielding effectiveness.

2. The shielding article of claim 1, wherein the non-conductive polymeric layer comprises at least one of polyester, polyimide, polyamide-imide, polytetrafluoroethylene, polypropylene, polyethylene, polyphenylene sulfide, polyethylene naphthalate, polycarbonate, silicone rubber, ethylene propylene diene rubber, polyurethane, acrylate, silicone, natural rubber, and synthetic rubber adhesive.

3. The shielding article of claim 1, wherein the non-conductive polymeric layer comprises a first non-conductive polymeric sublayer, a second non-conductive polymeric sublayer, and a bonding adhesive layer disposed between the first non-conductive polymeric sublayer and the second non-conductive polymeric sublayer.

4. The shielding article of claim 1, wherein the non-conductive polymeric layer has a thickness in the range of 5 μm to 500 μm.

5. The shielding article of claim 1, wherein the first and second conductive layers have a different thickness.

6. The shielding article of claim 1, wherein the first and second conductive layers have substantially the same thickness.

7. The shielding article of claim 1, wherein the first and second conductive layers have a thickness in the range of 100 to 30000 Angstroms.

8. The shielding article of claim 1, wherein one or both of the first and second conductive layers comprise a layer of copper disposed on a layer of nickel.

9. The shielding article of claim 8, wherein the layer of copper has a thickness in the range of 50 to 2000 Angstroms.

10. The shielding article of claim 8, wherein the layer of copper has a thickness in the range of 800 to 2000 Angstroms.

11. The shielding article of claim 8, wherein the layer of nickel has a thickness in the range of 25 to 125 Angstroms.

12. The shielding article of claim 8, wherein the layer of nickel has a thickness in the range of 50 to 100 Angstroms.

13. The shielding article of claim 1 further comprising a protective layer disposed adjacent one or both of the first conductive layer and the second conductive layer.

14. The shielding article of claim 13, wherein the protective layer comprises a polyester paper coated with an inorganic coating.

15. The shielding article of claim 13, wherein the protective layer comprises an aramid paper.

16. The shielding article of claim 1 further comprising an adhesive layer disposed on one or both of the first conductive layer and the second conductive layer.

17. The shielding article of claim 16, wherein the adhesive layer comprises one of a pressure sensitive adhesive, a hot melt adhesive, a thermoset adhesive, and a curable adhesive.

18. The shielding article of claim 16, wherein the adhesive layer comprises a corrosion inhibitor.

19. A shielding article comprising:
a plurality of conductive layers, each conductive layer spaced apart from an adjacent conductive layer by a non-conductive polymeric layer defining a separation distance,
wherein the conductive layers cooperatively provide a first shielding effectiveness, and wherein the conductive layers and separation distances cooperatively provide a second shielding effectiveness that is greater than the first shielding effectiveness.
